(19) United States
(12) Patent Application Publication
(10) Pub. No.: US 2017/0148941 A1
(43) Pub. Date: May 25, 2017

(54) METHOD FOR MANUFACTURING SOLAR CELL MODULE

(71) Applicant: Panasonic Intellectual Property Management Co., Ltd., Osaka (JP)

(72) Inventors: Masaharu TAKENAKA, Osaka (JP); Kei NAKAMURA, Osaka (JP)

(73) Assignee: Panasonic Intellectual Property Management Co., Ltd., Osaka (JP)

(21) Appl. No.: 15/422,467

(22) Filed: Feb. 2, 2017

Related U.S. Application Data
(63) Continuation of application No. PCT/JP2015/003796, filed on Jul. 29, 2015.

(30) Foreign Application Priority Data
Aug. 4, 2014 (JP) 2014-158411

(51) Int. Cl. H01L 31/049; B32B 37/10

(52) U.S. Cl. CPC H01L 31/049; B32B 37/10; B32B 2457/00

(57) ABSTRACT

Embodiments include an exemplary method for manufacturing a solar cell module that includes: a front surface-side transparent protective member having a curved shape; a back surface-side protective member having a curved shape corresponding to the curved shape of the front surface-side transparent protective member; and a filler layer disposed between the front surface-side transparent protective member and the back surface-side protective member, and seals a solar cell inside. The exemplary method may comprise: preparing the front surface-side transparent protective member having the curved shape and the back surface-side protective member having the curved shape; and manufacturing the solar cell module by disposing the solar cell and the filler layer between the front surface-side transparent protective member and the back surface-side protective member, and by pressing the front surface-side transparent protective member, the back surface-side protective member, the solar cell, and the filler layer.

### CROSS REFERENCE TO RELATED APPLICATIONS

This application is a U.S. continuation application of PCT International Patent Application Number PCT/JP2015/003796 filed on Jul. 29, 2015, claiming the benefit of priority of Japanese Patent Application Number 2014-158411 filed on Aug. 4, 2014, the entire contents of which are hereby incorporated herein by reference.

### BACKGROUND

1. Technical Field

The present disclosure relates to a method for manufacturing a solar cell module.

Solar cells are installed in houses, and electrical power generated by the solar cells is used domestically or sold to power companies. Although solar cells have been previously installed mainly on flat roofs, installing solar cells in places other than the roofs is being considered. Patent Literature (PLT) 1 (Japanese Unexamined Patent Application Publication No. H05-5344) discloses that flat panel solar cells are provided on a transparent glass roofing material having a curved surface.

2. Description of the Related Art

When solar cells are mounted on a curved surface, the need arises for a solar cell module which fits a curved shape. A solar cell module is typically obtained by disposing a filler layer which includes, for example, resin and seals a solar cell inside, between a front surface-side transparent protective member including, for example, a glass plate and a back surface-side protective member including, for example, a resin sheet which is flexible.

FIG. 7 is a diagram illustrating a schematic cross-sectional view of a conventional method for manufacturing a solar cell module having a curved shape. As illustrated in FIG. 7, filler layer 30 seals solar cells 31 inside and is mounted on front surface-side transparent protective member 10 having a curved shape. After plate-like back surface-side protective member 50, which is flexible, is mounted on filler layer 30, back surface-side protective member 50, filler layer 30, and front surface-side transparent protective member 10 are pressed to manufacture a solar cell module. Each solar cell 31 is electrically connected via wiring member 32 in filler layer 30.

FIG. 8 is a diagram illustrating a schematic cross-sectional view of a solar cell module 2 resulting from the pressing performed in the state illustrated in FIG. 7. As illustrated in FIG. 8, with the conventional method, back surface-side protective member 50 does not fit a curved surface, and many creases are formed in back surface-side protective member 50.

An object of the present disclosure is to provide a method for manufacturing a solar cell module having a curved shape, the method making it possible to prevent creases from forming in a back surface-side protective member.

### SUMMARY

A method for manufacturing a solar cell module according to one aspect is a method for manufacturing a solar cell module including: a front surface-side transparent protective member having a curved shape; a back surface-side protective member having a curved shape corresponding to the curved shape of the front surface-side transparent protective member; and a filler layer disposed between the front surface-side transparent protective member and the back surface-side protective member, and seals a solar cell inside, the method comprising: preparing the front surface-side transparent protective member having the curved shape and the back surface-side protective member having the curved shape; and manufacturing the solar cell module by disposing the solar cell and the filler layer between the front surface-side transparent protective member and the back surface-side protective member, and by pressing the front surface-side transparent protective member, the back surface-side protective member, the solar cell, and the filler layer.

With the aspect of the present disclosure, the method for manufacturing the solar cell module having a curved shape makes it possible to prevent creases from forming in the back surface-side protective member.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a diagram illustrating a schematic cross-sectional view of a solar cell module according to one or more embodiments.

FIG. 2 is a diagram illustrating a schematic perspective view of the solar cell module according to one or more embodiments.

FIG. 3 is a flow chart illustrating operations for manufacturing the solar cell module according to one or more embodiments.

FIG. 4 is a diagram illustrating a schematic cross-sectional view corresponding to an operation for manufacturing a solar cell module by mounting a back surface-side protective member having a curved shape on a filler layer mounted on a front surface-side transparent protective member having a curved shape, and pressing the back surface-side protective member, the filler layer, and the front surface-side protective member.

FIG. 5 is a diagram illustrating a schematic cross-sectional view of a state of an operation in which a back surface-side protective member having a plate shape is mounted on a mold having a curved shape.

FIG. 6 is a diagram illustrating a schematic cross-sectional view of a state of an operation in which a back surface-side protective member is heated on the mold to give the back surface-side protective member a curved shape.

FIG. 7 is a diagram illustrating a schematic cross-sectional view of a conventional method for manufacturing a solar cell module.

FIG. 8 is a diagram illustrating a schematic cross-sectional view of a solar cell module manufactured by a convention method, such as is illustrated in FIG. 7.

### DETAILED DESCRIPTION OF THE EMBODIMENTS

The following describes a method for manufacturing a solar cell module according to one or more embodiments, with reference to the drawings. However, the following one or more embodiments are merely an example and does not limit the scope of the present disclosure. The numerical values, shapes, materials, structural elements, the arrangement and connection of the structural elements, etc. shown in the following one or more embodiments are mere examples, and therefore do not limit the scope of the present disclosure. Structural elements having essentially the same functions may share the same reference numbers in the figures.

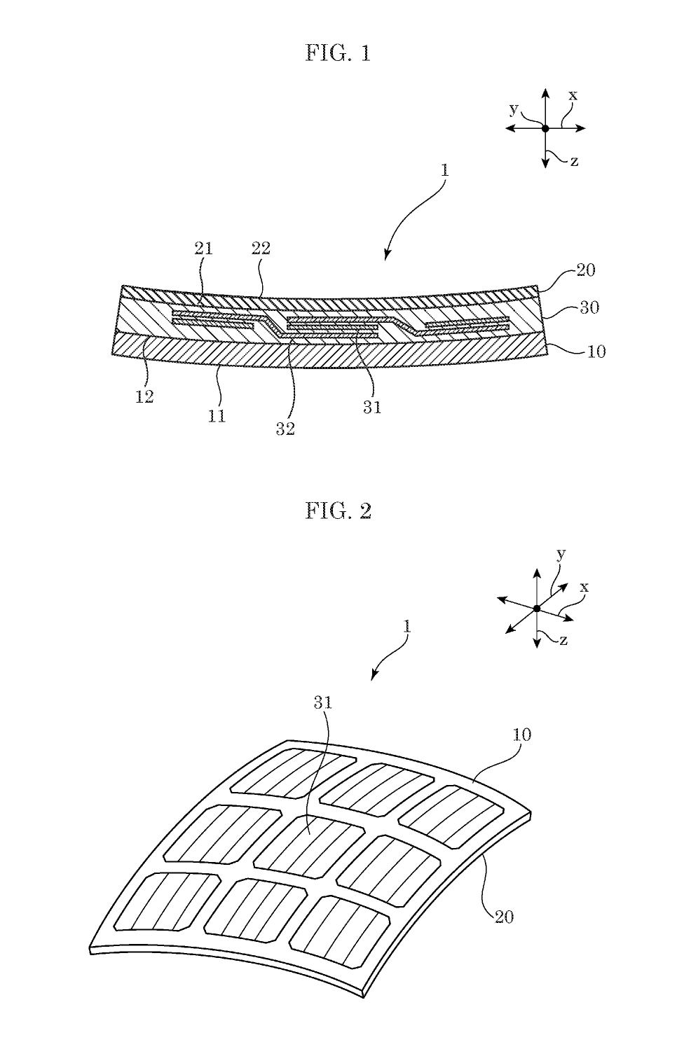

FIG. 1 is a schematic cross-sectional view illustrating a solar cell module according to one or more embodiments. As illustrated in FIG. 1, solar cell module 1 according to one or more embodiments includes: a front surface-side transparent protective member 10; a back surface-side protective member 20; and a filler layer 30 disposed between the front surface-side transparent protective member 10 and the back surface-side protective member 20, and seals solar cells 31 inside.

A first principal surface 11 on a front surface side of front the surface-side protective member 10 and a second principal surface 12 on a back surface side of the front surface-side protective member 10 each have a curved shape bulging toward the front surface side. In addition, a first principal surface 21 on a front surface side of the back surface-side protective member 20 and a second principal surface 22 on a back surface side of the back surface-side protective member 20 each also have a curved shape bulging toward the front surface side. The curved shape of the back surface-side protective member 20 corresponds to the curved shape of the front surface-side protective member 10. Each solar cell of the solar cells 31 is electrically connected via a wiring member 32 in the filler layer 30.

FIG. 2 is a diagram illustrating a schematic perspective view of the solar cell module according to one or more embodiments illustrated in FIG. 1. As illustrated in FIG. 2, the curved shape of the front surface-side protective member 10 and the curved shape of the back surface-side protective member 20 bulge toward the front surface side and curve in an x direction and a y direction perpendicular to the x direction. Accordingly, the curved shape of the front surface-side protective member 10 and the curved shape of the back surface-side protective member 20 constitute a three-dimensionally curved shape.

In an example, the front surface side transparent protective member 10 may include a glass plate or a transparent resin plate such as an acryl plate and a polycarbonate plate. The filler layer 30 may include a crosslinking resin such as an ethylene-vinyl acetate (EVA) copolymer or a non-crosslinking resin such as polyolefin.

In one or more embodiments, the back surface-side protective member 20 includes a flexible sheet material. Examples of the flexible sheet material include a resin sheet material such as polyvinylidene fluoride (PVF), polyethylene terephthalate (PET), and polytetrafluoroethylene (PTFE). In addition, the sheet flexible material may be formed by laminating metal foils such as aluminum foils. A thickness of the back surface-side protective member 20 is in a range of from 50 μm to 350 μm, and more specifically in a range of from 130 μm to 250 μm.

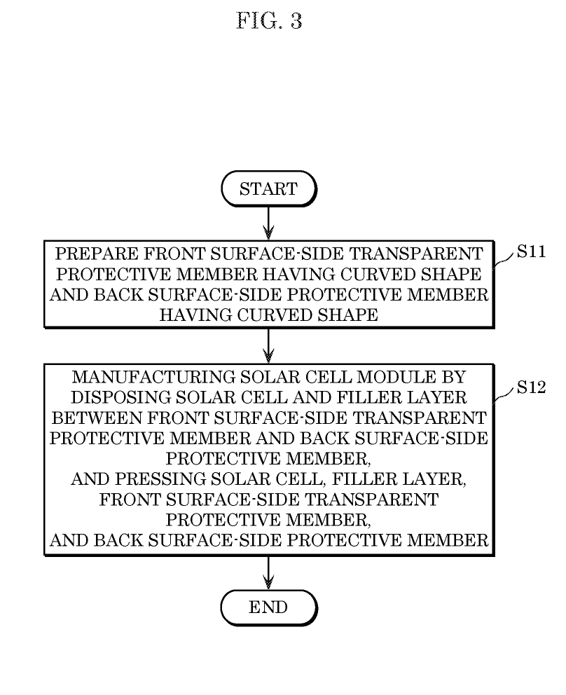

FIG. 3 is a flow chart illustrating operations for manufacturing the solar cell module according to one or more embodiments.

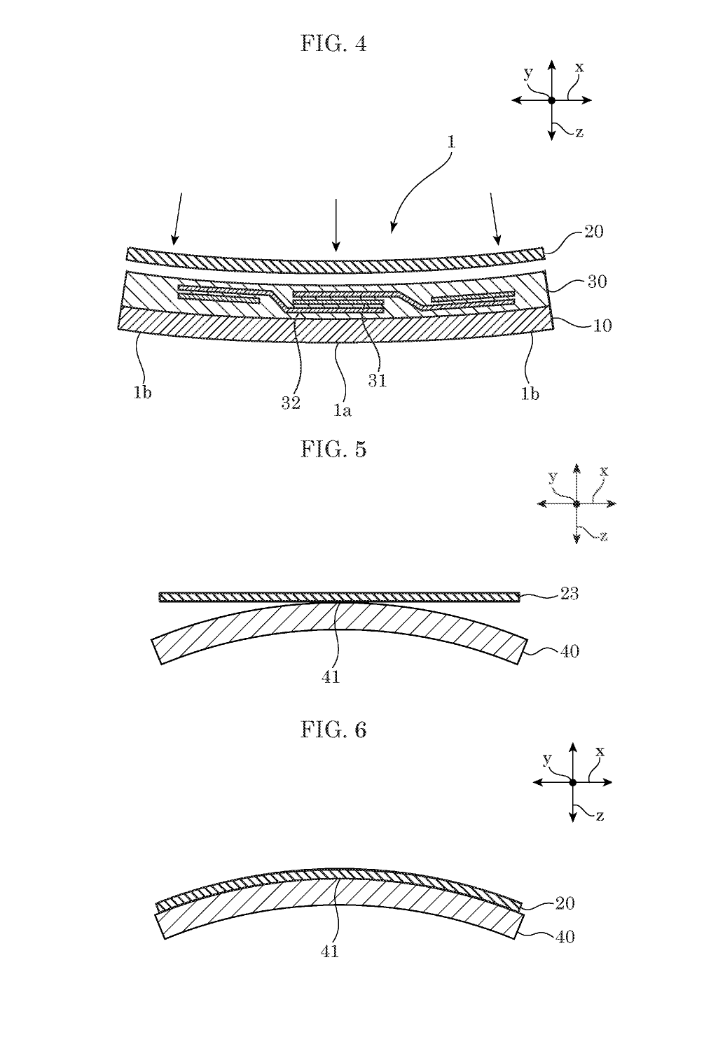

FIG. 4 is a diagram illustrating a schematic cross-sectional view corresponding to an operation for manufacturing the solar cell module according to one or more embodiments.

First, front surface-side transparent protective member 10 having a curved shape and back surface-side protective member 20 having a curved shape are prepared (Step S11).

Specifically, front surface-side transparent protective member 10 having the curved shape is prepared. Front surface-side transparent protective member 10 having the curved shape may be produced by bending a glass plate or a resin plate having a plate shape, by heat, cutting, or like mechanism or operation. In addition, the front surface-side transparent protective member 10 having the curved shape may be produced by pressing the front surface-side transparent protection member 10 using a metal mold, or like mechanism or operation. The back surface-side transparent protective member 20 having the curved shape is also prepared.

Next, the solar cell module 1 is manufactured by disposing the solar cells 31 and the filler layer 30 between the front surface-side transparent protective member 10 and the back surface-side protective member 20, and pressing the front surface-side transparent protective member 10, the back surface-side protective member 20, the solar cells 31, and the filler layer 30 (Step S12).

Specifically, a crosslinking resin or non-crosslinking resin sheet which is to be filler layer 30 is laminated on front surface-side transparent protective member 10, and solar cells 31 electrically connected via wiring member 32 are disposed on the crosslinking resin or non-crosslinking resin sheet. Another crosslinking resin or non-crosslinking resin sheet which is to be filler layer 30 is disposed on solar cells 31.

Next, as illustrated in FIG. 4, the back surface-side protective member 20 having a curved shape is laminated on the filler layer 30. Subsequently, the resulting laminated body is pressed by heat. Consequently, it is possible to manufacture the solar cell module 1 in which the front surface-side transparent protective member 10, the filler layer 30, and the back surface-side protective member 20 are laminated.

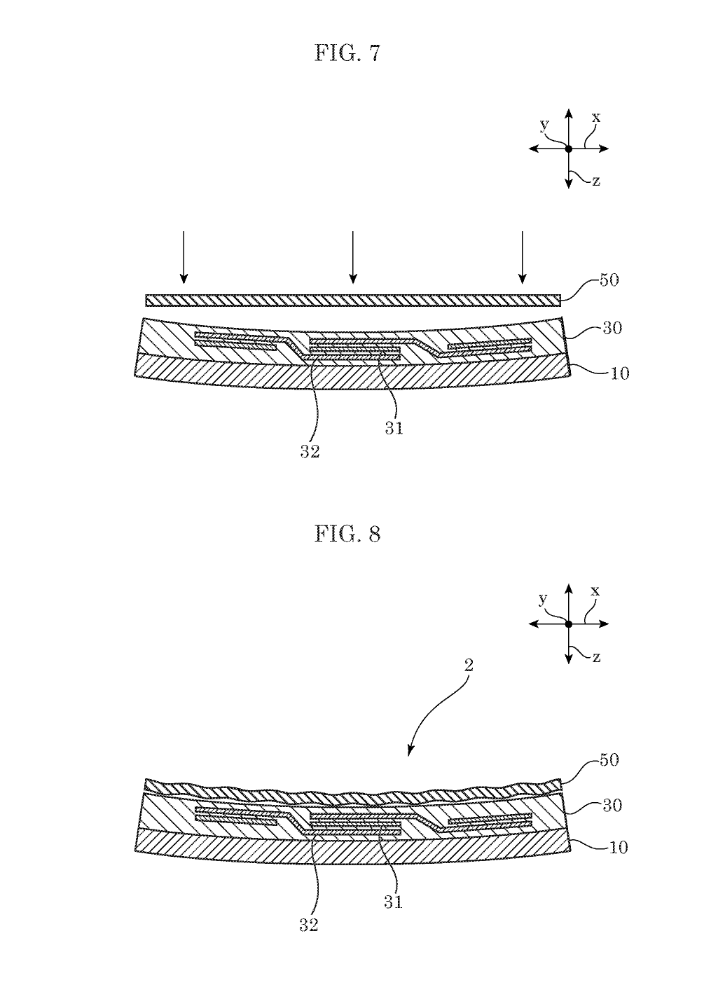

In one or more embodiments, unlike the conventional method illustrated with reference to FIG. 7 and FIG. 8, the back surface-side protective member 20 to which a curved shape is previously given, is used instead of the back surface-side protective member 50 having a plate shape. For this reason, it is possible to prevent creases from forming in the back surface-side protective member 20. Accordingly, in one or more embodiments, it is further possible to improve an appearance of the solar cell module 1.

A heating temperature for pressing may be a temperature at which the back surface-side protective member 20 is not deteriorated by heat. Specifically, the temperature is in a range of from 100° C. to 240° C., and more specifically in a range of from 120° C. to 180° C. Moreover, the solar cell module 1 may be heated to cause a peripheral portion 1b of the solar cell module 1 in a planar direction (x direction and y direction) to have a higher temperature than a central portion 1a of the solar cell module 1 in the planar direction. Stated differently, the solar cell module 1 may be heated to cause the peripheral portion 1b of the solar cell module 1 in a plan view to have a higher temperature than the central portion 1a of the solar cell module 1 in the plan view. The difference in temperature between the peripheral portion 1b and central portion 1a is in a range of from 20° C. to 50° C., and more specifically in a range of from 40° C. to 50° C. Setting such a difference in temperature allows peripheral portion 1b to actively expand and contract by heat to easily fit the curved shape, which makes it possible to easily perform processing.

FIG. 5 and FIG. 6 are diagrams each illustrating a schematic cross-sectional view corresponding to an exemplary operation for giving a curved shape to a back surface protective member having a plate shape. FIG. 5 illustrates a state of an operation where the back surface-side protective member 23 having a plate shape is mounted on a mold having a curved shape. A top surface 41 of a mold 40 has a curved shape to be given to the back surface-side protective member 23. Suction ports which are not illustrated are formed in the top surface 41. The back surface-side protective member 23 is held above the top surface 41 of the mold 40 by being sucked through the suction ports. In the state illustrated in FIG. 5, the back surface-side protective member 23 is heated to fit a shape of the top surface 41 of the mold 40. Specifically, the back surface-side protective member 23 is heated to soften, and an own weight of the back surface-side protective member 23 and the suction through the suction ports formed in the top surface 41 cause the back surface-side protective member 23 to stick to the top surface 41 of the mold 40. With this, the back surface-side protective member 23 is fitted to the shape of the top surface 41 of the mold 40.

FIG. 6 is a diagram illustrating a schematic cross-sectional view of a state of an operation where the back surface-side protective member is given a curved shape. As illustrated in FIG. 6, a curved shape fitted to the shape of the top surface 41 of the mold 40 is given to the back surface-side protective member 20.

As illustrated with reference to FIG. 4, the solar cell module 1 according to one or more embodiments may be manufactured using the back surface-side protective member 20 having a curved shape thus obtained. However, a method for giving a back surface-side protective member a curved shape is not limited to the method described in one or more embodiments.

Although the exemplary three-dimensionally curved shape has been illustrated and described as a curved shape that curves in the x direction and the y direction in one or more embodiments, the present disclosure is not so limited. For example, a three-dimensionally curved shape that curves only in the x direction or only the y direction is possible.

Moreover, although the exemplary curved shape has been illustrated and described as a curved shape bulging toward the front surface side(convex shape) of solar cell module 1, the present disclosure is not so limited. For example, a curved shape bulging toward the back surface side (concave shape) of solar cell module 1 may be possible within the scope of one or more embodiments.

While the foregoing has described one or more embodiments and/or other examples, it is understood that various modifications may be made thereto and that the subject matter disclosed herein may be implemented in various forms and examples, and may be applied in numerous applications, only some of which have been described herein. Thus, it is intended that embodiments be bounded by the following claims and any and all equivalents, modifications and variations that fall within the scope thereof based on the present teachings.

What is claimed is:

1. A method for manufacturing a solar cell module including: a front surface-side transparent protective member having a curved shape; a back surface-side protective member having a curved shape corresponding to the curved shape of the front surface-side transparent protective member; and a filler layer disposed between the front surface-side transparent protective member and the back surface-side protective member, and that seals a solar cell inside, the method comprising:
preparing the front surface-side transparent protective member having the curved shape and the back surface-side protective member having the curved shape; and
manufacturing the solar cell module by disposing the solar cell and the filler layer between the front surface-side transparent protective member and the back surface-side protective member, and by pressing the front surface-side transparent protective member, the back surface-side protective member, the solar cell, and the filler layer.

2. The method according to claim 1,
wherein the back surface-side protective member comprises a flexible sheet material.

3. The method according to claim 1,
wherein when the pressing is performed, the solar cell module is heated to cause a peripheral portion of the solar cell module in a plan view to have a higher temperature than a central portion of the solar cell module in the plan view.

4. The method according to claim 1,
wherein each of the curved shapes comprises a three-dimensionally curved shape.
